(19) United States
(12) Patent Application Publication
(10) Pub. No.: US 2024/0012517 A1
(43) Pub. Date: Jan. 11, 2024

(54) DISPLAY ARRANGEMENT AND METHOD

(71) Applicant: Lumineq Oy, Espoo (FI)

(72) Inventors: Gerald SMID, Espoo (FI); Jonne LINDEBERG, Espoo (FI)

(21) Appl. No.: 17/780,640

(22) PCT Filed: Nov. 25, 2020
(86) PCT No.: PCT/FI2020/050794

§ 371 Date: May 27, 2022

(30) Foreign Application Priority Data
Nov. 29, 2019 (FI) 20196037

(51) Int. Cl. G06F 3/041; H10K 59/40; G06F 3/044; G09G 3/3208

(52) U.S. Cl. CPC G06F 3/04184; H10K 59/40; G06F 3/0412; G06F 3/044; G09G 3/3208; G09G 3/04

(57) ABSTRACT

A display arrangement (100) comprises a thin film display element (101), comprising an emissive layer (103); first and second patterned conductor layers (104, 105) comprising first and second display electrodes (110, 120), respectively; and a touch electrode. The display arrangement (100) comprises a display driver unit (180) to couple activation electrical voltage (311) between the display electrodes (110, 120) during a first (310) and a second (330) emission-activation period and maintain the display electrodes (110, 120) at substantially equal potentials throughout an intermediate period (320) between the emission-activation periods (310, 320). The display arrangement (100) comprises a control unit (170) to measure, during an emission period formed by the first emission-activation period (310) and the intermediate period, touch-dependent capacitive coupling for the touch electrode (130) throughout at least one measurement period (325) lying outside the rising (311′) and the falling period (311″).

### BACKGROUND

A display device comprising a display element, such as an inorganic thin film electroluminescent (TFEL) display element or a thin film organic light-emitting diode (OLED) display element, may be provided with various types of input devices for controlling an information processing system connected with the display device.

For example, an electrical display device may comprise a touch-sensitive input device laminated onto a display element. However, addition of a touch-sensitive input device or element onto a display element increases the complexity of the structure and manufacturing of the latter, and may also impair the optical properties of the display element.

On the other hand, touch-sensitive displays with a higher level of integration may exhibit increased probability of compatibility issues between individual elements or units. In light of this, it may be desirable to develop new solutions related to displays and touch-sensitive input devices thereof.

### SUMMARY

This summary is provided to introduce a selection of concepts in a simplified form that are further described below in the Detailed Description. This Summary is not intended to identify key features or essential features of the claimed subject matter, nor is it intended to be used to limit the scope of the claimed subject matter.

According to a first aspect, a display arrangement is provided. The display arrangement comprises a thin film display element with a layer structure extending substantially along a base plane defining a lateral extension of the display element.

The thin film display element comprises an emissive layer configured to emit light in consequence of electrical voltage coupled over the emissive layer; a first patterned conductor layer on a first side of the emissive layer, comprising a first display electrode; a second patterned conductor layer on a second side of the emissive layer opposite the first side, comprising a second display electrode at least partly laterally overlapping the first display electrode; and a touch electrode formed in the first and/or the second patterned conductor layer.

The display arrangement comprises a display driver unit configured to couple activation electrical voltage between the first and the second display electrode during a first and a second emission-activation period and maintain the first and the second display electrode at substantially equal potentials throughout an intermediate period between the first and the second emission-activation period, each of the first and the second emission-activation period comprising a rising period and a falling period during which a magnitude of a voltage between the first and the second display electrode changes from substantially zero to substantially a magnitude of the activation electrical voltage and vice versa, respectively.

The display arrangement further comprises a control unit configured to measure, during an emission period formed by the first emission-activation period and the intermediate period, touch-dependent capacitive coupling for the touch electrode throughout at least one measurement period lying outside the rising period and the falling period.

According to a second aspect, a method for concurrent light emission and touch detection using a thin film display element is provided. The thin film display element may be in accordance with any embodiment of the first aspect disclosed in this specification.

The method comprises coupling activation electrical voltage between the first and the second display electrode during a first and a second emission-activation period, each of the first and the second emission-activation period comprising a rising period and a falling period during which a magnitude of a voltage between the first and the second display electrode changes from substantially zero to substantially a magnitude of the activation electrical voltage and vice versa, respectively; maintaining the first and the second display electrode at substantially equal potentials throughout an intermediate period between the first and the second emission-activation period; and measuring, during an emission period formed by the first emission-activation period and the intermediate period, touch-dependent capacitive coupling for the touch electrode throughout at least one measurement period lying outside the rising period and the falling period.

It is specifically to be understood that a display arrangement and a control unit may operate a thin film display arrangement according to a method in accordance with the second aspect.

### BRIEF DESCRIPTION OF DRAWINGS

The present disclosure will be better understood from the following detailed description read in light of the accompanying drawings, wherein:

FIG. 1 depicts a partly cross-sectional, schematic illustration of a display arrangement,

FIG. 2 shows a partly cross-sectional, schematic illustration of another display arrangement,

FIG. 3 illustrates a timing diagram for concurrent light emission and touch detection, and

FIG. 4 illustrates a method for concurrent light emission and touch detection using a thin film display element.

Unless specifically stated to the contrary, any drawing of the aforementioned drawings may be not drawn to scale such that any element in said drawing may be drawn with inaccurate proportions with respect to other elements in said drawing in order to emphasize certain structural aspects of the embodiment of said drawing.

Moreover, corresponding elements in the embodiments of any two drawings of the aforementioned drawings may be disproportionate to each other in said two drawings in order to emphasize certain structural aspects of the embodiments of said two drawings.

### DETAILED DESCRIPTION

Concerning display arrangements and methods discussed in this detailed description, the following shall be noted.

Herein, a “display”, or a “display panel”, may refer to a device, e.g., electronic device, configured to present data or imagery. The aforementioned terms may be understood broadly in the context of this specification, naturally covering displays capable of displaying various patterns, images, or text, but also, for example, various control panels and user interface elements with at least one emissive area for emitting light therefrom.

Further, a “display arrangement” may refer to an arrangement which may form, as such, a complete, operable display. Alternatively, a display arrangement may be used as a part of a complete display comprising also other elements, units, and/or structures. A display arrangement may generally comprise at least one display element.

Throughout this specification, a “display element” may refer to an element comprising at least one emissive area for emitting light therefrom in order to present visual information.

Herein, “light” may refer to electromagnetic radiation of any wavelength(s) within a range of relevant wavelengths. The range of relevant wavelengths may overlap or coincide with ultraviolet (wavelength from about nanometers (nm) to about 400 nm), visible (wavelength from about 400 nm to about 700 nm), and/or infrared (wavelength from about 700 nm to about 1 millimeter (mm)) parts of electromagnetic spectrum.

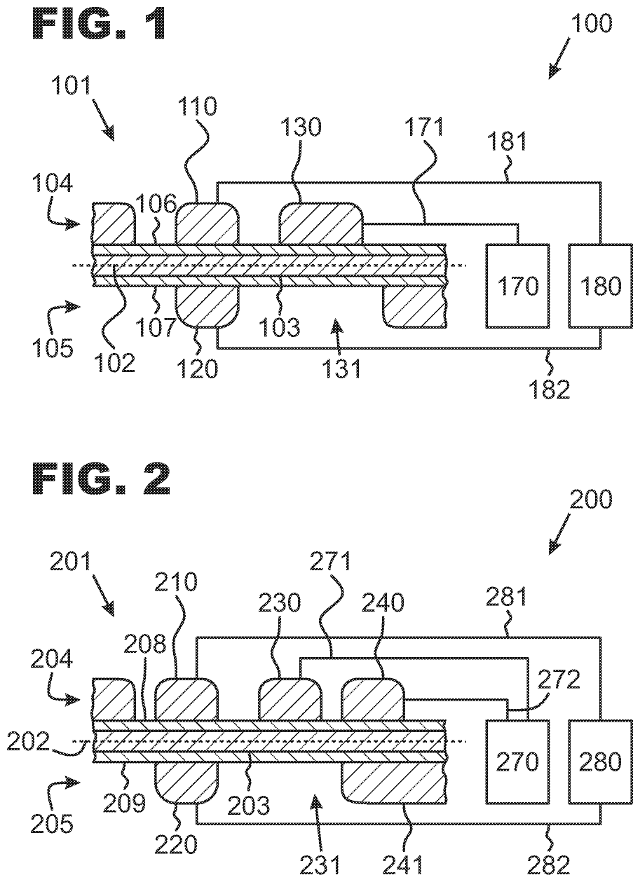

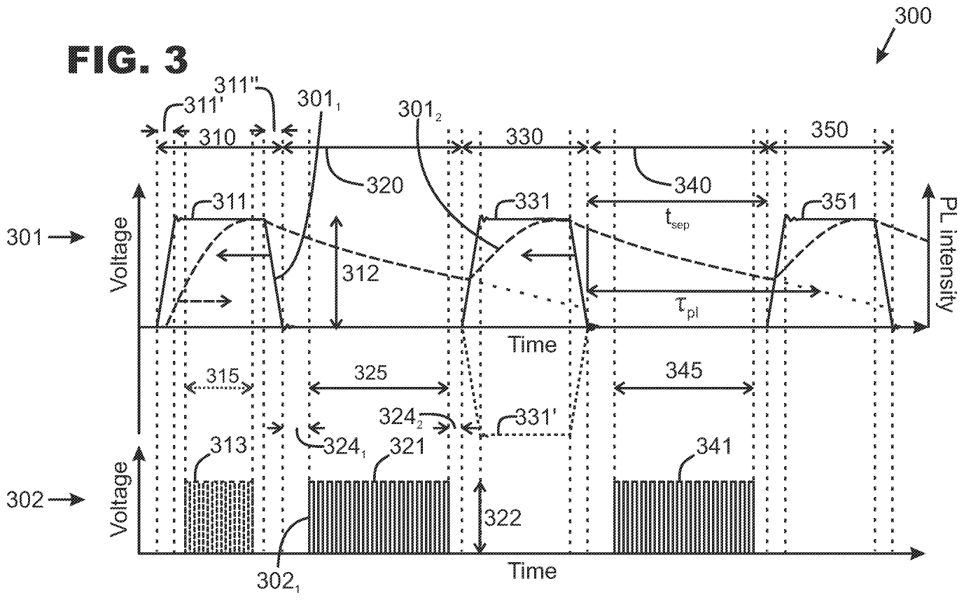

FIG. 1 depicts a partly cross-sectional, schematic illustration of a display arrangement 100 according to an embodiment. Although not explicitly shown in FIG. 1, the embodiment of FIG. 1 or any part thereof may generally comprise any features and/or elements of any of the embodiments of FIGS. 2 to 3 which are omitted from FIG. 1.

In the embodiment of FIG. 1, the display arrangement 100 comprises a transparent thin film display element 101 with a layer structure extending substantially along a fictitious base plane 102 defining a lateral extension of the thin film display element 101. In other embodiments, thin film display elements may be used which are not transparent.

Herein, a “layer” may refer to a generally sheet-formed element arranged on a surface or a body. Additionally or alternatively, a layer may refer to one of a series of superimposed, overlaid, or stacked generally sheet-formed elements. A layer may generally comprise a plurality of sublayers of different materials or material compositions. A layer may be path-connected. Some layers may be locally path-connected and disconnected.

In this disclosure, a base plane “defining a lateral extension” of an element with a layer structure may refer to said element comprising a layer and having lateral directions along said base plane, in which lateral directions said element may have dimensions substantially larger than in a thickness direction perpendicular to said lateral directions.

Herein, a “thin film” display element may refer to a display element having a total thickness less than or equal to 50 micrometers (μm), or less than or equal to 20 μm, or less than or equal to 10 μm. Individual layers may have thicknesses, for example, in a range from a few nanometers to some hundreds of nanometers or some micrometers.

The base plane 102 of the embodiment of FIG. 1 is planar. In other embodiments, a thin film display element may be curved, extending substantially along a curved base plane. Further, although illustrated as a planar structure in FIG. 1, the base plane 102 may be formed as a rollable, flexible, and/or bendable structure. Consequently, a base plane may generally be variable.

In the embodiment of FIG. 1, the thin film display element 101 comprises an emissive layer 103. The emissive layer 103 is configured to emit light in consequence of electrical voltage coupled over the emissive layer 103.

In this specification, an “emissive layer” may refer to layer comprising material capable of emitting light when electrical voltage is coupled over said emissive layer.

The thin film display element 101 of the embodiment of FIG. 1 further comprises a first patterned conductor layer 104 on a first side of the emissive layer 103.

Throughout this specification, a “conductor” may refer to an electrical conductor material and/or the electrical conductivity thereof. Consequently, a “conductor layer” may refer to a layer comprising a conductor material. Additionally or alternatively, a conductor layer may be electrically non-insulating, e.g., electrically conductive.

A conductor layer may comprise, for example, indium tin oxide (ITO), aluminum-doped zinc oxide (AZO, ZnO:Al), any other appropriate transparent conductive oxide (TCO), and/or any other transparent conductor material. Additionally or alternatively, a conductor layer may comprise, for example, a thin metal mesh. Such layers, with sufficiently low thicknesses, may be transparent.

Throughout this specification, an element or material being “transparent”, may refer to a quality, i.e., “transparency”, of said element or material of allowing light of wavelength(s) within a range of relevant wavelengths to propagate through such element or material. Said range of relevant wavelengths may generally depend on intended usage of such transparent element or material.

Herein, a “patterned” layer may refer to a layer extending non-uniformly throughout an extent thereof. Additionally of alternatively, a patterned layer may refer to a structure comprising one or more discontinuities. Additionally or alternatively, a patterned layer may be locally path-connected and disconnected. Additionally or alternatively, a patterned layer may comprise a hole in a topological (homeomorphism) sense.

Such patterned nature of a layer may be implemented by several patterns, the patterns being separated from each other. In some embodiments, a patterned layer may be implemented with just one pattern. Then, the “patterned” nature of said layer may be implemented with the pattern not covering an underlying surface entirely, i.e., at least one opening or region exists in an area of said underlying surface which is not covered by said layer. Naturally, a “patterned conductor layer” may refer to a conductor layer with corresponding features.

Any appropriate patterning processes may generally be used to pattern a patterned conductor layer. Such patterning process may comprise several stages, such as cleaning, drying, photoresist coating, pre-baking, exposure, developing, etching, and/or stripping with cleaning/drying steps. For example, lithographic patterning for ITO as the material of a conductor layer may be carried out with an automated photolithography in-line tool utilizing wet-chemical processes. A selected etchant, which may be, for example, a mixture of hydrochloric acid (HCl) and nitric acid (HNO₃), removes the desired areas of the conductor layer.

The first patterned conductor layer 104 of the thin film display element 101 of the embodiment of FIG. 1 comprises a first display electrode 110.

Throughout this specification, a “display electrode” may refer to an electrode suitable for coupling electrical voltage over an emissive layer. A display electrode may be functionally, electrically, and/or galvanically connected to a display driver unit, in order to supply said electrical voltage. Additionally or alternatively, a display electrode may at least partly, i.e., partly or entirely, laterally overlap another display electrode in order to enable coupling electrical voltage over an emissive layer.

In the embodiment of FIG. 1, the thin film display element 101 comprises a second patterned conductor layer 105 on a second side of the emissive layer 103. The second side is opposite the first side. The second patterned conductor layer 105 comprises a second display electrode 120. The second display electrode 120 substantially completely laterally overlaps the first display electrode 110. In other embodiments, a second display electrode may laterally overlap a first display electrode at least partly. A second display electrode at least partly overlapping a first display electrode may enable coupling electrical voltage over an emissive layer.

In the embodiment of FIG. 1, the thin film display element 101 comprises two patterned conductor layers 104, 105. In other embodiments, a thin film display element may comprise at least one, e.g., two, or three, or more, patterned conductor layers on a first side of an emissive layer and at least one, e.g., two, or three, or more, patterned conductor layers on a second side of an emissive layer opposite the first side. In general, a thin film display element comprising a reduced number of conductor layers may exhibit higher brightness, transparency, and/or optical clarity.

The thin film display element 101 of the embodiment of FIG. 1 is specifically implemented as an inorganic thin film electroluminescent (TFEL) display element. Consequently, the thin film display element 101 of the embodiment of FIG. 1 comprises a first insulating layer 106 arranged between the emissive layer 103 and the first patterned conductor layer 104, as well as a second insulating layer 108 arranged between the emissive layer 103 and the second patterned conductor layer 105. In other embodiments, a thin film display element may or may not be implemented as an inorganic TFEL display element. A thin film display element may generally be implemented as any suitable type of display element.

Herein, an “inorganic thin film electroluminescent” type of display element may refer to a thin film display element comprising an emissive layer comprising an inorganic phosphor material layer. In inorganic TFEL displays, an alternating or pulsed driving voltage may be applied over such emissive layer. Such alternating or pulsed driving voltage may have a period, for example, of some milliseconds or tens of milliseconds. Peak-to-peak amplitudes of such driving voltages may be, for example, few hundreds of volts (V), generated by a specific display driver unit and coupled between first and second display electrodes via conductors from output terminals of said display driver unit. In inorganic TFEL displays, a first insulating layer may be arranged between an emissive layer and a first patterned conductor layer, and a second insulating layer may be arranged between said emissive layer and a second patterned conductor layer.

The thin film display element 101 of the embodiment of FIG. 1 is specifically implemented as a segment-type thin film display element. In other embodiments, a display arrangement may comprise a segment-type and/or any other suitable type of thin film display element, such as a matrix-type thin film display element.

In this disclosure, a “segment-type” display element may refer to a display element in which emissive areas form individually or group-by-group controllable segments of letters, numbers, and/or other distinctive symbols. On the other hand, a “matrix-type” display element may refer to a display element in which conductor patterns of two patterned conductor layers define emissive parts of an emissive layer at locations where said conductor patterns overlap. In a matrix-type display, at least one conductor pattern may be involved in defining a plurality (e.g., at least two) emissive parts.

Although not illustrated in FIG. 1, a transparent thin film display element may generally be formed on any appropriate substrate or carrier. Said substrate may be formed, for example, of glass, e.g., sodalime, aluminosilicate, and/or any other appropriate transparent glass, or plastic. Suitable plastic materials include, for example, polyethylene (PE), polycarbonate (PC), and mixtures thereof, without being limited to these examples.

A substrate or carrier may mechanically protect a thin film display element and/or serve as an electrically insulating layer between said thin film display element and surroundings thereof. Further, there may also be another protective and/or insulating layer on an opposite side of said thin film display element. Such another layer may be formed by an external layer or element to which a display element is attached.

In the embodiment of FIG. 1, the display arrangement 100 further comprises a display driver unit 180, as illustrated schematically in FIG. 1. Additionally, an electrical first display connection 181 exists between the display driver unit 180 and the first display electrode 110, and an electrical second display connection 182 exists between the display driver unit 180 and the second display electrode 120. In some embodiments, a display driver unit may be implemented as a separate unit, whereas in others a display driver unit may be implemented as a sub-unit of a control system further comprising any other suitable sub-units.

Although each of the first display connection 181 and the second display connection 182 of FIG. 1 is illustrated schematically as being separated from the first patterned conductor layer 104 and the second patterned conductor layer 105, any electrical connection existing between a unit and an electrode may generally be formed at least partly in a patterned conductor layer.

Throughout this specification, a “display driver unit” may refer to a device or part of an electrical circuit configured to provide power for bringing about emission of light by an emissive layer.

A unit being “configured to” perform a process may refer to capability of and suitability of said unit for such process. This may be achieved in various ways.

For example, a unit may comprise at least one processor and at least one memory coupled to the at least one processor, the memory storing program code instructions which, when executed on said at least one processor, cause the processor to perform the process(es) at issue.

Additionally or alternatively, any functionally described features of any unit may be performed, at least in part, by one or more hardware logic components. For example, and without limitation, illustrative types of suitable hardware logic components include Field-programmable Gate Arrays (FPGAs), Application-specific Integrated Circuits (ASICs), Application-specific Standard Products (ASSPs), System-on-a-chip systems (SOCs), Complex Programmable Logic Devices (CPLDs), etc.

The display driver unit 180 of the embodiment of FIG. 1 is configured to couple activation electrical voltage between the first display electrode 110 and the second display electrode 120 during a first and a second emission-activation period and maintain the first display electrode 110 and the second display electrode 120 at substantially equal potentials throughout an intermediate period between the first and the second emission-activation period, wherein each of the emission-activation periods comprises a rising period and a falling period during which magnitude of a voltage between the first display electrode 110 and the second display electrode 120 changes from substantially zero to substantially a magnitude of the activation electrical voltage and vice versa, respectively.

An “emission-activation period” may refer to a period of time during which electrical voltage of sufficient magnitude, which may be called activation electrical voltage, is supplied between a first and a second display electrode to bring about emission of light by a part of an emissive layer between said display electrodes. In some cases, a part of an emissive layer between a first and a second display electrode may emit light only during said emission-activation periods.

An “intermediate period” may refer to a period of time between two sequential emission-activation periods. Thereby, an emission-activation period may be separated from another emission-activation period by an intermediate period.

Depending on the electrical and/or electronical configuration of a display driver unit, the voltage coupled between the first and the second display electrode of a display arrangement may be changeable from its initial value to another one not suddenly but during a transition time only. Depending whether the magnitude of the voltage increases or decreases, such transition time may be called a rising period or a falling period, respectively.

Hence, a “rising period” may refer to a period of time during which a magnitude of the voltage between a first and a second display electrode changes from substantially zero to substantially a magnitude of an activation electrical voltage.

Correspondingly, a “falling period” may refer, to a period of time during which the magnitude of a voltage between a first and a second display electrode changes from substantially zero to substantially a magnitude of an activation electrical voltage.

Depending on the configuration of the display driver unit of a display arrangement, the change of the voltage may take place, for example, via a rapid initial change followed by a damping oscillation around the target value. Alternatively, the change may take place via exponential increase or decrease toward the target value.

A rising period may be defined, for example, as the time period during which the magnitude of a voltage between a first and a second display electrode raises from substantially zero and settles within a range of 95-105% of the magnitude of an activation electrical voltage.

Herein, “magnitude of an activation electrical voltage” may refer to an absolute value of activation electrical voltage coupled between a first and a second display electrode during a first and/or a second emission-activation period. Additionally or alternatively, magnitude of an activation electrical voltage may refer to an absolute value of minimum electrical voltage required to bring about emission of light by a part of an emissive layer between a first and a second display electrode.

Correspondingly, a falling period may be defined, for example, as the time period during which the magnitude of a voltage between a first and a second display electrode falls from substantially the magnitude of an activation electrical voltage and settles within a range of +/−5% of the magnitude of the activation electrical voltage, thus close to zero.

The thin film display element 101 of the embodiment of FIG. 1 further comprises a touch electrode 130 and a control unit 170. The touch electrode 130 is formed in the first patterned conductor layer 104.

The control unit 170 is configured to measure, during an emission period formed by the first emission-activation period and the intermediate period, touch-dependent capacitive coupling for the touch electrode 130 throughout at least one measurement period which lies outside the rising period and the falling period.

A “measurement period” may refer to a period of time throughout which touch-dependent capacitive coupling is measured for a touch electrode. A measurement period may specifically refer to any period of time during or throughout which a measurement voltage signal is supplied to an electrode.

During a measurement period, a first and a second display electrode may generally be maintained at substantially equal potentials or there may be an activation electrical voltage coupled between them.

One or more measurement periods may lie within an emission-activation period, outside the rising and falling period.

Irrespective of possible measurement period(s) lying within an emission-activation period, one or more measurement periods may lie within an intermediate period.

A period lying within another period refers to the former period starting not earlier than the latter period and ending not later than the latter period.

From the light emission point of view, in some embodiments, a part of an emissive layer between a first and a second display electrode may emit light during a measurement period. In other embodiments, however, such part of an emissive layer may be not emitting light during a measurement period.

The display driver unit 180 and the control unit 170 may or may not form sub-units of a single control system. In other embodiments, a control unit may be configured to measure capacitive coupling for as many touch electrodes as suitable or necessary for any given application. In said other embodiments, a touch electrode may be formed in a first and/or a second patterned conductor layer.

In this specification, a “control unit” may refer to a device, e.g., an electronic device, having at least one specified function related to determining and/or influencing an operational condition, status, or parameter related to another device, unit, or element. Said device, unit, or element may herein refer at least to a touch electrode of a thin film display element. A control unit may generally be operated in accordance with any appropriate methods, e.g., charge transfer, relaxation oscillator, successive approximation, or sigma-delta modulator methods, and by means of any appropriate circuitry and signals known in the art for capacitive touch sensing. A control unit may or may not form a part of a multifunctional control system.

Herein, “touch-dependent capacitive coupling” may refer to capacitance as a physical quantity measurable for an element or between elements. Said capacitance may generally vary based on a material distribution in the surroundings of said element(s). Additionally or alternatively, touch-dependent capacitive coupling may refer to capacitance as an operational condition, status, or parameter indicative of or representing said physical quantity. In general, changes in capacitive coupling between at least part of an electrical circuit and a body extraneous to said circuit may affect an operational condition or status of said circuit. Such changes may be brought about by a touch, especially in case said electrical circuit comprises a touch electrode specifically configured for capacitive touch sensing. Consequently, changes in capacitive coupling may be associated with touch inputs, and a touch-based input arrangement may be devised based on detecting changes in capacitive coupling. Such approach may generally be referred to as capacitive touch sensing.

Herein, a “touch” may refer to any change in distance between a pointing object, such as a finger, and a touch electrode resulting in a detectable change in coupling capacitance between said pointing object and said touch electrode. Additionally or alternatively, a touch may refer to any spatial arrangement of such pointing object and a touch electrode resulting in a detectable change in an operational condition, status, or parameter related to said touch electrode compared to a predefined standard condition, status, or parameter, respectively. As such, “touch sensing” may herein refer to touch and/or proximity sensing. Further, a “touch electrode” may refer to an electrode suitable for capacitive touch sensing and/or to at least part of a touch sensor for capacitive touch sensing.

Generally, a display driver unit and a control unit as described above may significantly facilitate concurrent light-emission and reliable touch detection using a display arrangement, even in the absence of any additional layers in a thin film element. Reliability of touch detection may be improved due to reduced interference arising from variations or changes in display supply voltage. Additionally or alternatively, such features may enable forming electrodes in patterned conductor layers of said thin film display element at a higher areal density.

In the embodiment of FIG. 1, an electrical touch connection 171 exists between the control unit 170 and the touch electrode 130. Therefore, the control unit 170 controls the touch electrode 130 directly. In other embodiments, a control unit may control a touch electrode directly, or indirectly by controlling a separate intermediate controller, which in turn is electrically connected with said touch electrode and carries out actual touch electrode control operations.

In the embodiment of FIG. 1, the second patterned conductor layer 105 comprises an opening 131 at the location of the touch electrode 130. Such opening may generally improve a touch sensitivity of a display arrangement. In other embodiments, wherein one of a first and a second patterned layer comprises a touch electrode, the other patterned conductor layer may or may not comprise an opening at the location of said touch electrode.

The control unit 170 of the embodiment of FIG. 1 is specifically configured, when measuring touch-dependent capacitive coupling for the touch electrode 130, to supply a measurement voltage signal to the touch electrode, said touch-dependent capacitive coupling being indicative of a self-capacitance of the touch electrode. Such features may generally enable forming a touch-sensitive display arrangement with a reduced number of electrodes and/or electrical interconnections.

Herein, “self-capacitance” of an element may refer to a physical quantity of a non-insulating body, e.g., an electrode, indicative of a ratio between added electrical charge in said body and an increase in electrical potential of said body. Measurement of self-capacitance may be referred to as measurement of capacitance with respect to infinity. In practice, measurement of self-capacitance may refer to measuring capacitance with respect to electrical ground, e.g., earth ground.

Additionally or alternatively, a control unit being configured to measure capacitive coupling “indicative of a self-capacitance” may refer to said control unit being operated in accordance with principles of self-capacitive touch technology.

FIG. 2 depicts a partly cross-sectional, schematic illustration of a display arrangement 200 according to an embodiment. Although not explicitly shown in FIG. 2, the embodiment of FIG. 2 or any part thereof may generally comprise any features and/or elements of any of the embodiments of FIGS. 1 and 3 which are omitted from FIG. 2.

The display arrangement 200 of the embodiment of FIG. 2 comprises a thin film display element 201 with a layer structure extending substantially along a base plane 202. The thin film display element 201 comprises an emissive layer 203, a first 210 and a second display electrode 220, and a touch electrode 230.

In the embodiment of FIG. 2, the second patterned conductor layer 205 comprises an opening 231 at the location of the touch electrode 230 and an electrically floating passive electrode pattern 241 at the location of the transmitter electrode 240. Such features may generally improve a touch sensitivity of a display arrangement. In other embodiments, comprising a touch electrode and a transmitter electrode, a thin film display element may or may not comprise patterned conductor layer(s) with opening(s) and/or passive electrode pattern(s) at the locations of said electrodes.

In the embodiment of FIG. 2, the display arrangement 200 comprises a display driver unit 280, as illustrated schematically in FIG. 2. Additionally, an electrical first display connection 281 exists between the display driver unit 280 and the first display electrode 210, and an electrical second display connection 282 exists between the display driver unit 280 and the second display electrode 220.

The display arrangement 200 of the embodiment of FIG. 2 further comprises a control unit 270, which is schematically shown in FIG. 2, configured to measure touch-dependent capacitive coupling for the touch electrode 230.

In the embodiment of FIG. 2, the thin film display element 201 comprises a transmitter electrode 240 in the first patterned conductor layer 204, and the control unit 270 is configured, when measuring touch-dependent capacitive coupling for the touch electrode, to supply a measurement voltage signal to the transmitter electrode 240, said touch-dependent capacitive coupling being indicative of a mutual capacitance between the transmitter electrode 240 and the touch electrode. Such features may generally facilitate sensing distant pointing object(s).

In other embodiments, a thin film display element may or may not comprise a transmitter electrode in a first and/or a second patterned conductor layer. In some embodiments, a thin film display element may comprise a transmitter electrode having a first part extending in a first patterned layer, a second part extending in a second patterned conductor layer, and a connecting part connecting said first and second parts. In some embodiments, a thin film display element may comprise a plurality of transmitter electrodes. Generally, a transmitter electrode extending in only one patterned conductor layer may be sufficient under practical circumstances, especially in case of a display element having a total thickness less than or equal to 50 μm, or less than or equal to 20 μm, or less than or equal to 10 μm.

In this specification, “mutual capacitance” may refer to capacitance occurring between two electrically chargeable bodies. Additionally or alternatively, a control unit being configured to measure capacitive coupling “indicative of a mutual capacitance” may refer to said control unit being operated in accordance with principles of projected capacitive (PCAP) touch technology. In PCAP touch technology, touch is detected on the basis of a change of a coupling capacitance between two electrodes, caused by the introduction and/or removal of dielectric and possibly lossy media of a touching member, e.g., a human finger, sufficiently close to said two electrodes.

In the embodiment of FIG. 2, an electrical touch convection 271 exists between the control unit 270 and the touch electrode 230 and an electrical transmitter connection 272 exists between the control unit 270 and the transmitter electrode 240. Therefore, the control unit 270 controls the touch electrode 230 and the transmitter electrode 240 of the thin film display element 201 directly. In other embodiments, a control unit may control a touch electrode and/or a transmitter electrode directly or indirectly.

Generally, a display element may be of any type, e.g., inorganic TFEL or an OLED display element, irrespective of whether said display element comprises a transmitter electrode. As such, the thin film display element 201 of the embodiment of FIG. 2 may be implemented, for example, as an inorganic TFEL display element or a thin film organic light-emitting diode (OLED) display element, a particular type of TFEL display element.

An “an organic light-emitting diode display element” may herein refer to a display element with an emissive layer comprising organic light-emitting molecules and/or polymers. Additionally, an OLED display element may comprise a number of auxiliary layers between such emissive layer and a patterned conductor layer in order to improve an efficiency of said OLED display element. Such auxiliary layers of an OLED display element may correspond to electron/hole blocking, electron/hole transport, and/or electron/hole injection layers. In some embodiments, OLED display elements with different auxiliary layers may be used.

In the embodiment of FIG. 2, the thin film display element 201 comprises a first auxiliary layer 208 arranged between the emissive layer 203 and the first patterned conductor layer 204, as well as a second auxiliary layer 209 arranged between the emissive layer 103 and the second patterned conductor layer 205. If the thin film display element 201 is implemented as an inorganic TFEL display element, the first 208 and the second auxiliary layer 209 may correspond to a first and a second insulating layer, respectively. In other embodiments, a thin film display element may or may not comprise one or more auxiliary layers.

FIG. 3 illustrates a timing diagram 300 for concurrent light emission and touch detection using a thin film display element of a display arrangement, which may be in accordance with any embodiment disclosed within this specification.

The timing diagram 300 of FIG. 3 consists of a first graph 301 with two y-axes labeled “Voltage” and “PL intensity” as well as a second graph 302 with a single y-axis labeled “Voltage”. The two y-axes labeled “Voltage” are drawn with different scales. The first graph 301 comprises a first curve 301₁ indicating a voltage between a first and a second display electrode as a function of time, and a second curve 301₂ indicating a relative photoluminescence intensity measurable for a part of an emissive layer between the first and second display electrodes. The second graph 302 comprises a curve 302₁ indicating a voltage between a measurement electrode, i.e., a touch electrode or a transmitter electrode, and a pre-defined reference potential, such as a control unit ground potential.

The total period of time illustrated in the timing diagram 300 comprises a first 310, a second 330, and a third 350 emission-activation period, as well as a first intermediate period 320 between the first and the second emission-activation period, and a second intermediate period 340 between the second and the third emission-activation period. Additionally, a first 325 and a second 345 measurement period exist in the first and the second intermediate period 320, 340, respectively. In the embodiment of FIG. 3, any number of measurement, intermediate, and/or emission-activation periods may follow the third emission-activation period 350.

The display arrangement of the embodiment of FIG. 3 serves as an example of a display arrangement, wherein emission-activation periods and measurement periods alternate. In other embodiments, emission-activation periods and measurement periods may or may not alternate.

During each emission-activation period 310, 330, 350, a display driver unit is configured to couple activation electrical voltage between the first and second display electrodes. In particular, a first, a second, and a third rectangular voltage pulse 311, 331, 351 are supplied between the first and second display electrodes by the display driver unit during the first 310, second 330, and third 350 emission-activation periods, respectively. Such supply of activation electrical voltage between the display electrodes results in an increase in photoluminescence intensity of the part of an emissive layer between the display electrodes.

In the embodiment of FIG. 3, the voltage of the pulses 311, 331, 351 is positive. In other embodiments, negative voltage pulses 331′, such as that illustrated in the first graph 301 by a dashed line, may be used. In some embodiments, activation electrical voltages supplied between a first and a second display electrode during a first and a second emission-activation period may be of different polarities, whereas in others such voltages may be of the same polarity.

As illustrated in the first graph 301, each of those basically rectangular voltage pulses comprises a rising edge where, during a rising period 311′, the magnitude of the voltage between the first and second display electrodes changes from substantially zero to substantially the magnitude of the activation electrical voltage. Correspondingly, each pulse also has a falling edge where, during a falling period 311″, the voltage between the first and the second electrodes changes from substantially zero to substantially the magnitude of the activation electrical voltage. In the embodiment of FIG. 3, the rising period and the falling period have similar durations. In other embodiments, it may be possible that a rising period and a falling period of an emission-activation period have different durations.

The display driver unit of the embodiment of FIG. 3 is further configured to maintain the first and the second display electrode at substantially equal potentials throughout each intermediate period 320, 340. As such, voltage between the display electrodes is substantially zero throughout each intermediate period 320, 340. In other embodiments, a display driver unit may be configured to maintain a first and a second display electrode at substantially equal or equal potentials throughout an intermediate period. In said other embodiments, said potentials may or may not vary from one intermediate period to another.

A first and a second display electrode being maintained at “substantially equal” potentials may refer to a voltage between said electrodes staying within a predefined range of voltages centered at 0 V and having lower and upper limit voltages proportional or comparable to a root mean square value of electrical voltage coupled between said display electrodes by a display driver unit during an emission-activation period. For example, such lower and upper limit voltages may be separated by a voltage difference having a magnitude less than or equal to 0.1, 0.05, or 0.01 times said root mean square value. In embodiments, wherein a display driver unit is configured to couple activation electrical voltage of substantially constant amplitude between a first and a second display electrode during an emission-activation period, a first and a second display electrode being maintained at substantially equal potentials may refer to a voltage between said electrodes staying within a predefined range of voltages centered at 0 V and having lower and upper limit voltages proportional or comparable to said substantially constant amplitude.

In the embodiment of FIG. 3, voltage between the display electrodes stays substantially zero throughout an intermediate period 320 starting immediately after the first emission-activation period 310 and ending immediately before the second emission-activation period 330. In other embodiments, such voltage may or may not stay substantially zero throughout such intermediate period. In some embodiments, pre-defined procedures may be executed during such intermediate periods, resulting in a substantially non-zero voltage between display electrodes. Additionally or alternatively, effects related to electrical inductance and/or capacitance may result in a substantially non-zero voltage between display electrodes.

In the embodiment of FIG. 3, different intermediate periods have similar lengths. In other embodiments, different intermediate periods may be identical, similar, or different lengths. Similar considerations may apply, mutatis mutandis, to any time period starting immediately after a measurement period and ending immediately before an emission-activation period.

Referring to the second graph 302 of FIG. 3, throughout each measurement period 325, 345, a control unit is configured to measure touch-dependent capacitive coupling for a touch electrode, which may or may not correspond to the measurement electrode. In the embodiment of FIG. 3, the control unit is configured, when measuring touch-dependent capacitive coupling for the touch electrode, to supply a measurement voltage signal to the measurement electrode, said touch-dependent capacitive coupling being indicative of either a self-capacitance of the measurement electrode, if the measurement electrode corresponds to the touch electrode, or a mutual capacitance between the measurement electrode and the touch electrode. In other embodiments, a control unit may or may not be configured in such manner.

The control unit of the embodiment of FIG. 3 supplies a first 321 and a second 341 measurement voltage signal to the measurement electrode throughout the first 325 and the second 345 measurement period, respectively. Each of the measurement voltage signals 321, 341 comprises a plurality of rectangular voltage pulses. In other embodiments, a control unit may or may not supply a measurement voltage signal to a measurement electrode, which measurement voltage signal may or may not comprise a plurality of pulses, such as rectangular pulses.

A measurement voltage signal suitable for measuring touch-dependent capacitive coupling may generally have a peak-to-peak amplitude, for example, of some volts or tens of volts. In some embodiments, a measurement voltage may have a period of some microseconds or tens of microseconds. Since a period of such measurement voltage signal may be several orders of magnitude shorter than a period of an alternating or pulsed driving voltage of an inorganic TFEL display element, in some embodiments, an inorganic thin film display element may be supplied with a driving voltage having a waveform possessing common features with waveforms of conventional inorganic TFEL display driving voltages.

In the embodiment of FIG. 3, the first and the second measurement period 325, 345 lie in, thus occur during, the first 320 and the second 340 intermediate period, respectively. In other embodiments, measurement periods 315 such as that illustrated in the second graph 302 may lie in emission-activation periods. Throughout or during such measurement period, measurement voltage signal 313 such as that illustrated in the second graph 302 by a dashed line may be supplied to the measurement electrode.

Further, differently from the example of FIG. 3, in other embodiments there may be a plurality of measurement periods in one single emission-activation period outside the rising and falling period thereof, and/or in one single intermediate period.

In some embodiments, activation electrical voltages supplied between a first and a second display electrode during a first and a second emission-activation period may be of different polarities, and one or more measurement periods may lie within one or more of the first and the second emission-activation period, outside the rising periods and falling periods of said one or more emission-activation periods.

For example, in an embodiment, activation electrical voltages supplied between a first and a second display electrode during a first and a second emission-activation period are of different polarities, and a measurement period lies within the first emission-activation period, outside the rising period and falling period thereof.

In another exemplary embodiment, activation electrical voltages supplied between a first and a second display electrode during a first and a second emission-activation period are of different polarities, and a measurement period lies within the second emission-activation period, outside the rising period and falling period thereof.

In yet another exemplary embodiment, activation electrical voltages supplied between a first and a second display electrode during a first and a second emission-activation period are of different polarities; a first measurement period lies within the first emission-activation period, outside the rising period and falling period thereof; and a second measurement period lies within the second emission-activation period, outside the rising period and falling period thereof.

In the embodiment of FIG. 3, each measurement period is separated from the rising and falling periods of the emission-activation periods by a standby period 324₁, 324₂. A standby period may have a duration, for example, of 1-30%, 3-15%, or 5-8% of a rising or falling period. A standby period may ensure that coupling of activation electrical voltage between two display electrodes does not interfere with the touch measurement.

In the embodiment of FIG. 3, an amplitude ratio between an amplitude 312 of electrical voltage during the first emission-activation period 310 and a highest peak-to-peak amplitude 322 of the first measurement voltage signal 321 is at least 20. In other embodiments, an amplitude ratio between an amplitude of electrical voltage coupled by a display driver unit between a first and a second display electrode during a first and/or a second emission-activation period and a highest peak-to-peak amplitude of a measurement voltage signal may or may not be at least 20, or at least 25, or at least 30. Generally, such amplitude ratio may severely aggravate touch sensing reliability issues caused by interference arising from variations in display supply voltage. High amplitude ratios may be typical, for example, of display arrangements comprising inorganic TFEL display elements.

The first 310 and second 330, and the second 330 and third 350 emission-activation periods of the embodiment of FIG. 3 are separated by a time separation tₛₑₚ, which is less than or equal to 20 milliseconds (ms). In the embodiment of FIG. 3, the time separation tₛₑₚ equals the duration of the intermediate periods 320, 340. Such a time separation between a preceding and a subsequent emission-activation period may reduce a perceived flickering of a display arrangement. In other embodiments, a time separation tₛₑₚ between successive emission-activation periods may or may not be less than or equal to 20 ms, or less than or equal to 15 ms, or less than or equal to 10 ms.

The emissive layer of the embodiment of FIG. 3 comprises a light-emitting material having a photoluminescence decay time τₚₗ greater than the time separation tₛₑₚ. In some embodiments, an emissive layer may comprise a light-emitting material having a photoluminescence decay time τₚₗ equal to a time separation tₛₑₚ between a preceding and a subsequent emission-activation period. Such features may significantly reduce a perceived flickering of a display arrangement and/or mitigate a reduction of average photoluminescence intensity caused by a discontinuous display supply voltage. In other embodiments, an emissive layer may or may not comprise a light-emitting material having a photoluminescence decay time τₚₗ greater than or equal to a time separation tₛₑₚ between a preceding and a subsequent emission-activation period.

Throughout this specification, a “photoluminescence decay time” may refer to a parameter indicative of a length of a time required for a photoluminescence intensity of a light-emitting material or element to decrease to 1/e≈36.8% of its initial value, following a step decrease in excitation, e.g., driving voltage. Additionally or alternatively, a photoluminescence decay time may refer to an exponential photoluminescence decay constant.

In the embodiment of FIG. 3, similar time separations exist between the first 310 and second 330 as well as the second 330 and third 350 emission-activation periods. In other embodiments, different time separations between preceding and subsequent emission-activation periods may be identical, similar, or different.

Above, mainly structural aspects and functional features of display arrangements are discussed. In the following, more emphasis will lie on method aspects related to concurrent light emission and touch detection. What is said above about the ways of implementation, definitions, details, and advantages applies, mutatis mutandis, to the method aspects discussed below. The same applies vice versa.

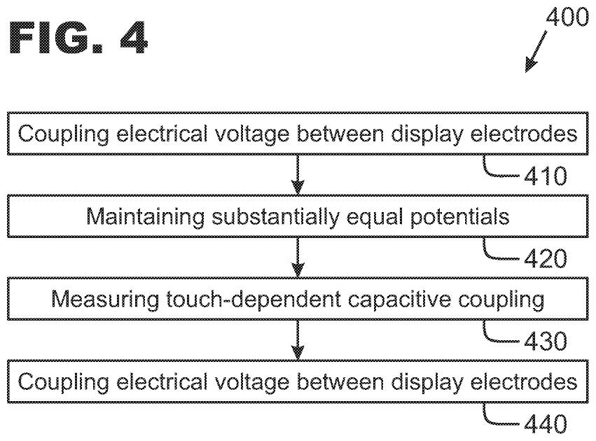

FIG. 4 illustrates a method 400 for concurrent light emission and touch detection using a thin film display element, which may be in accordance with any of the embodiments disclosed with reference to, in conjunction with, and/or concomitantly with any of FIGS. 1 to 3.

The method 400 of the embodiment of FIG. 4 comprises processes of coupling electrical voltage between display electrodes 410, whereby activation electrical voltage is coupled between a first and a second display electrode during a first emission-activation period; maintaining substantially equal potentials 420, whereby the first and the second display electrode are maintained at substantially equal potentials throughout an intermediate period after the first emission-activation period; measuring touch-dependent capacitive coupling 430; whereby touch-dependent capacitive coupling is measured for the touch electrode throughout a measurement period lying in the intermediate period; and coupling electrical voltage between display electrodes 440, whereby activation electrical voltage is coupled between the first and the second display electrode during a second emission-activation period after the intermediate period. The voltages and signals of the embodiment of FIG. 4 may thus be basically in accordance with the timing diagram of FIG. 3.

Generally, a method for concurrent light emission and touch detection using a thin film display element may comprise steps implementing processes corresponding to the processes 410, 420, 430, 440 of the method 400 of the embodiment of FIG. 4. Furthermore, a method for concurrent light emission and touch detection using a thin film display element may generally comprise any number of additional processes, steps, and/or features that are not disclosed herein in connection to the method 400 of the embodiment of FIG. 4.

For example, measurement periods may exist in emission-activation periods. Further, there may be more than one measurement period lying in an emission-activation period and/or an intermediate period. Additionally or alternatively, a time separation tₛₑₚ between a first and a second emission-activation period may be less than or equal to 20 ms. In such case, an emissive layer may or may not comprise a light-emitting material having a photoluminescence decay time τₚₗ greater than or equal to the time separation tₛₑₚ.

Irrespective of the means used for carrying out a method for concurrent light emission and touch detection using a thin film display element, any steps of the method may be performed at least partially automatically by means of suitable computing and/or data-processing means. Such means may comprise, for example, at least one processor and at least one memory coupled to the processor. The at least one memory may store program code instructions which, when run on the at least one processor, cause the processor to perform steps implementing various processes of the method. Additionally or alternatively, at least some of those steps may be carried out, at least partially, by means of some hardware logic elements or components, such as Application-specific Integrated Circuits (ASICs), Application-specific Standard Products (ASSPs), or System-on-a-chip systems (SOCs), without being limited to these specific examples.

It is obvious to a person skilled in the art that with the advancement of technology, the basic idea of the invention may be implemented in various ways. The invention and its embodiments are thus not limited to the examples described above, instead they may vary within the scope of the claims.

It will be understood that any benefits and advantages described above may relate to one embodiment or may relate to several embodiments. The embodiments are not limited to those that solve any or all of the stated problems or those that have any or all of the stated benefits and advantages.

The term “comprising” is used in this specification to mean including the feature(s) or act(s) followed thereafter, without excluding the presence of one or more additional features or acts. It will further be understood that reference to ‘an’ item refers to one or more of those items.

1. A display arrangement comprising a thin film display element with a layer structure extending substantially along a base plane defining a lateral extension of the display element, the thin film display element comprising:
an emissive layer configured to emit light in consequence of electrical voltage coupled over the emissive layer;
a first patterned conductor layer on a first side of the emissive layer, comprising a first display electrode;
a second patterned conductor layer on a second side of the emissive layer opposite the first side, comprising a second display electrode at least partly laterally overlapping the first display electrode;
a touch electrode formed in the first and/or the second patterned conductor layer; wherein
the display arrangement comprises a display driver unit configured to couple activation electrical voltage between the first and the second display electrode during a first and a second emission-activation period and maintain the first and the second display electrode at substantially equal potentials throughout an intermediate period between the first and the second emission-activation period, each of the first and the second emission-activation period comprising a rising period and a falling period during which a magnitude of a voltage between the first and the second display electrode changes from substantially zero to substantially a magnitude of the activation electrical voltage and vice versa, respectively; and
the display arrangement comprises a control unit configured to measure, during an emission period formed by the first emission-activation period and the intermediate period, touch-dependent capacitive coupling for the touch electrode throughout at least one measurement period lying outside the rising period and the falling period.

2. A display arrangement according to claim 1, wherein during the rising period, the magnitude of the voltage between the first and the second display electrode raises from substantially zero and settles within a range of 95-105% of the magnitude of the activation electrical voltage, and during the falling period, the magnitude of the voltage between the first and the second display electrode falls from substantially the magnitude of the activation electrical voltage and settles within a range of +/−5% of the magnitude of the activation electrical voltage.

3. A display arrangement according to claim 1, wherein the at least one measurement period lies outside the first and the second emission-activation period.

4. A display arrangement according to claim 1, wherein the control unit is configured, when measuring touch-dependent capacitive coupling for the touch electrode to supply a measurement voltage signal to the touch electrode said touch-dependent capacitive coupling being indicative of a self-capacitance of the touch electrode.

5. A display arrangement (200) according to claim 1, wherein the thin film display element comprises a transmitter electrode in the first and/or the second patterned conductor layer and the control unit is configured, when measuring touch-dependent capacitive coupling for the touch electrode to supply a measurement voltage signal to the transmitter electrode, said touch-dependent capacitive coupling being indicative of a mutual capacitance between the transmitter electrode and the touch electrode.

6. A display arrangement according to claim 4, wherein an amplitude ratio between an amplitude of the activation electrical voltage coupled by the display driver unit between the first and the second display electrode during the first and/or the second emission-activation period and a highest peak-to-peak amplitude of the measurement voltage signal is at least 20.

7. A display arrangement according to claim 1, wherein a time separation tₛₑₚ between the first and the second emission-activation period is less than or equal to 20 milliseconds, ms.

8. A display arrangement according to claim 7, wherein the emissive layer comprises a light-emitting material having a photoluminescence decay time τₚₗ greater than or equal to the time separation tₛₑₚ.

9. A display arrangement according to claim 1, wherein the thin film display element is implemented as a segment-type thin film display element.

10. A display arrangement according to claim 1, wherein the thin film display element is implemented as an inorganic thin film electroluminescent, TFEL, display element.

11. A display arrangement according to claim 1, wherein the thin film display element is implemented as a thin film organic light-emitting diode, OLED, display element.

12. A method for concurrent light emission and touch detection using a thin film display element in accordance with claim 1, the method comprising:
coupling activation electrical voltage between the first and the second display electrode during a first and a second emission-activation period, each of the first and the second emission-activation period comprising a rising period and a falling period during which a magnitude of a voltage between the first and the second display electrode changes from substantially zero to substantially a magnitude of the activation electrical voltage and vice versa, respectively;
maintaining the first and the second display electrode at substantially equal potentials throughout an intermediate period between the first and the second emission-activation period; and
measuring, during an emission period formed by the first emission-activation period and the intermediate period touch-dependent capacitive coupling for the touch electrode throughout at least one measurement period lying outside the rising period and the falling period.

13. A method according to claim 12, wherein during the rising period, the magnitude of the voltage between the first and the second display electrode raises from substantially zero and settles within a range of 95-105% of the magnitude of the activation electrical voltage, and during the falling period, the magnitude of the voltage between the first and the second display electrode falls from substantially the activation electrical voltage and settles within a range of +/−5% of the magnitude of the activation electrical voltage.

14. A method according to claim 12, wherein the at least one measurement period lies outside the first and the second emission-activation period.

15. A method (404) according to claim 12, wherein a time separation tₛₑₚ between the first and the second emission-activation period is less than or equal to 20 ms.

16. A method according to claim 15, wherein the emissive layer comprises a light-emitting material having a photoluminescence decay time τₚₗ greater than or equal to the time separation tₛₑₚ.
